(19) United States
(12) Patent Application Publication
(10) Pub. No.: US 2016/0351530 A1
(43) Pub. Date: Dec. 1, 2016

(54) SEMICONDUCTOR DEVICES AND PACKAGES INCLUDING CONDUCTIVE UNDERFILL MATERIAL AND RELATED METHODS

(71) Applicant: Micron Technology, Inc., Boise, ID (US)

(72) Inventors: Jaspreet S. Gandhi, Boise, ID (US); Luke G. England, Saratoga Springs, NY (US); Owen R. Fay, Meridian, ID (US)

(21) Appl. No.: 15/232,525

(22) Filed: Aug. 9, 2016

Related U.S. Application Data
(63) Continuation of application No. 13/851,788, filed on Mar. 27, 2013.

(51) Int. Cl. H01L 23/00; H01L 21/56; H01L 25/18; H01L 25/065; H01L 25/00

(52) U.S. Cl. CPC H01L 24/81; H01L 25/0657; H01L 25/50; H01L 25/18; H01L 24/16; H01L 21/563; H01L 2224/08225; H01L 2224/81125; H01L 2224/81024; H01L 2224/81815; H01L 2224/81203; H01L 2225/06513; H01L 2225/06544; H01L 2225/06555; H01L 2225/06582

(57) ABSTRACT

Semiconductor devices and device packages include at least one semiconductor die electrically coupled to a substrate through a plurality of conductive structures. The at least one semiconductor die may be a plurality of memory dice, and the substrate may be a logic die. An underfill material disposed between the at least one semiconductor die and the substrate may include a thermally conductive material. An electrically insulating material is disposed between the plurality of conductive structures and the underfill material. Methods of attaching a semiconductor die to a substrate, such as for forming semiconductor device packages, include covering or coating at least an outer side surface of conductive structures, electrically coupling the semiconductor die to the substrate with an electrically insulating material, and disposing a thermally conductive material between the semiconductor die and the substrate.

### CROSS-REFERENCE TO RELATED APPLICATION

This application is a continuation of U.S. patent application Ser. No. 13/851,788, filed Mar. 27, 2013, pending, the disclosure of which is hereby incorporated herein in its entirety by this reference.

### FIELD

Embodiments of the present disclosure relate to packaging techniques for mechanically and electrically connecting a semiconductor device to a substrate, such as connecting a semiconductor device having fine pitch conductive structures (e.g., solder balls, metal pillars) to a substrate or another semiconductor device using a conductive underfill material.

### BACKGROUND

There is a trend in the electronics industry to reduce the size of components of electronic devices. Such a reduction in size may enable reduced cost, increased efficiency, and lower energy requirements, among other benefits. Semiconductor device packages (e.g., memory, processors, light-emitting diodes (LEDs), micro-electromechanical system (MEMS) device packages, combinations thereof) have been the subject of a variety of size reduction efforts. For example, one method of reducing an area covered by a semiconductor device package includes stacking multiple semiconductor devices over each other and using through silicon vias (TSVs) to electrically couple the multiple semiconductor devices to an underlying substrate.

Some conventional semiconductor device packages include conductive structures (e.g., solder bumps, copper pillars) that electrically couple the semiconductor devices to each other and/or to an underlying substrate. An underfill material is disposed in a volume between the semiconductor devices to add physical stability to the package and to protect the conductive structures from environmental damage, such as by forming a moisture barrier. Conventional underfill materials are primarily dielectric materials such as polymers, although additives and filler materials may be included to alter the mechanical, chemical, and/or thermal properties of the underfill materials.

Semiconductor devices generate an undesirable amount of heat during operation. For example, logic devices (e.g., processors), dynamic random access memory (DRAM) devices, and complementary metal oxide semiconductor (CMOS) devices are known to generate significant heat during operation. If such devices are stacked with or covered by other semiconductor devices and encapsulated, covered with a lid, or both, such as in a semiconductor device package comprising multiple semiconductor devices, heat may become trapped and temperatures may rise to unacceptable levels within one or more of the semiconductor devices. Transferring heat away from semiconductor devices and substrates in a semiconductor device package may improve performance of the semiconductor devices and may reduce the potential for heat-induced damage to the semiconductor devices.

It is known to use epoxy flux, which includes an epoxy component and a flux component, to remove oxides from conductive elements (e.g., conductive structures, solder balls) of a semiconductor device during formation of electrical connections between the conductive elements of the semiconductor device and bond pads of a substrate. As or after the electrical connections are formed, the flux component is removed, such as by evaporation through heating. The epoxy component of the epoxy flux may be simultaneously or subsequently cured to form a solid epoxy that may structurally reinforce the bonding of the semiconductor device to the substrate. However, the thermal resistance of epoxy is relatively high (i.e., epoxy is generally not a good thermal conductor), and heat may be retained in a semiconductor device of the package by the thermally insulating epoxy. Such heat can damage and/or reduce performance of the semiconductor device package.

Fillers have been added to underfill materials to increase the thermal conduction through the underfill materials. For example, particles of a ceramic material have been used as a filler to improve heat transfer through underfill materials. However, ceramic fillers such as aluminum nitride and boron nitride are difficult to produce in spherical form and, when employed in flake form, may create difficulties in achieving a uniform, acceptably thin bond line and may perforate protective (e.g., passivation) layers. Electrically conductive particles (e.g., metal particles), which may exhibit greater thermal conductivity than ceramic particles or other electrically insulating particles, are generally avoided as fillers or used in limited concentrations to inhibit undesired electrical communication (e.g., shorts) between adjacent conductive structures of a semiconductor device package.

### BRIEF DESCRIPTION OF THE DRAWINGS

FIGS. 1 through 7 illustrate a method of attaching a semiconductor die to a substrate to form a semiconductor device package according to an embodiment of the present disclosure.

FIGS. 1 through 3 illustrate a process for coating fine pitch conductive structures of the semiconductor die with an epoxy flux according to an embodiment of the present disclosure.

FIG. 4 illustrates the semiconductor die positioned over the substrate, with the coated fine pitch conductive structures of the semiconductor die aligned with bond pads of the substrate.

FIG. 5 illustrates the semiconductor die placed on the substrate with the coated fine pitch conductive structures positioned over the bond pads of the substrate.

FIG. 6 illustrates the fine pitch conductive structures forming an electrical connection to the conductive features of the substrate.

FIG. 7 illustrates a portion of the semiconductor device package including an underfill material disposed in a volume between the semiconductor die and the substrate.

FIG. 8 is a cross-sectional top-down view of the portion of the semiconductor device package of FIG. 7, taken along line I-I of FIG. 7, according to an embodiment of the present disclosure.

FIG. 9 is a cross-sectional top-down view of a portion of a semiconductor device package similar to FIG. 8, according to another embodiment of the present disclosure.

FIG. 10 is a cross-sectional side view of a semiconductor device package according to an embodiment of the present disclosure.

### DETAILED DESCRIPTION

As used herein, the term “substantially” in reference to a given parameter means and includes to a degree that one of ordinary skill in the art would understand that the given parameter, property, or condition is met with a small degree of variance, such as within acceptable manufacturing tolerances. By way of example and not limitation, a parameter that is “substantially” met may be at least about 90% met, at least about 95% met, or even at least about 99% met.

As used herein, any relational term, such as “first,” “second,” “over,” “on,” “top,” “bottom,” “vertical,” “lateral,” etc., is used for clarity and convenience in understanding the disclosure and accompanying drawings and does not connote or depend on any specific preference, orientation, or order, except where the context clearly indicates otherwise.

The following description provides specific details, such as material types and processing conditions, in order to provide a thorough description of embodiments of the present disclosure. However, a person of ordinary skill in the art will understand that the embodiments of the present disclosure may be practiced without employing these specific details. Indeed, the embodiments of the present disclosure may be practiced in conjunction with conventional semiconductor fabrication techniques employed in the industry. In addition, the description provided below may not form a complete process flow for manufacturing semiconductor devices and packages. The structures described below do not necessarily form complete semiconductor devices or packages. Only those process acts and structures necessary to understand embodiments of the present disclosure are described in detail below. Additional acts to form complete semiconductor devices, packages, and systems may be performed by conventional fabrication techniques. Accordingly, only the methods and semiconductor device structures necessary to understand embodiments of the present disclosure are described herein.

In the following detailed description, reference is made to the accompanying drawings, which form a part hereof, and in which is shown, by way of illustration, specific embodiments in which the present disclosure may be practiced. These embodiments are described in sufficient detail to enable a person of ordinary skill in the art to practice the present disclosure. However, other embodiments may be utilized, and structural, logical, methodological, and compositional changes may be made without departing from the scope of the disclosure. The illustrations presented herein are not meant to be actual views of any particular system, device, structure, or package, but are merely idealized representations which are employed to describe the embodiments of the present disclosure. The drawings presented herein are not necessarily drawn to scale. Additionally, elements common between drawings may retain the same numerical designation. However, any similarity in numbering does not mean that the structures or components are necessarily identical in size, composition, configuration, or other property.

Embodiments of the present disclosure include methods of electrically and mechanically connecting, for example, a semiconductor die to a substrate, such as another semiconductor die (e.g., a memory die, a logic die), a printed circuit board, an interposer, etc., for forming a semiconductor device package. The methods include using an underfill material that may include thermally and electrically conductive filler material to facilitate heat transfer through the underfill material. Use of such an underfill material may maintain a sufficiently low temperature in at least one of the semiconductor die and the substrate to improve or maintain performance and reliability thereof. In addition, embodiments of the present disclosure include methods of forming a semiconductor device package using such underfill materials. To avoid or reduce electrical shorting between conductive structures (e.g., solder bumps, electrically conductive pillars, metal pillars, copper pillars) used to connect the semiconductor die to the substrate, the conductive structures may be at least partially coated in an epoxy flux prior to introducing the underfill material into a volume between the semiconductor die and the substrate. An epoxy component of the epoxy flux may form an electrically insulating barrier between the conductive structures and any adjacent, electrically conductive underfill material. The methods of the present disclosure may be useful, among other things, to attach a semiconductor die to a substrate where a plurality of fine pitch conductive structures are used to form electrical connections between the semiconductor die and the substrate. Thus, the embodiments of the present disclosure may enable the use of electrically conductive filler material (e.g., metal filler material) in underfill materials to substantially enhance thermal conductivity.

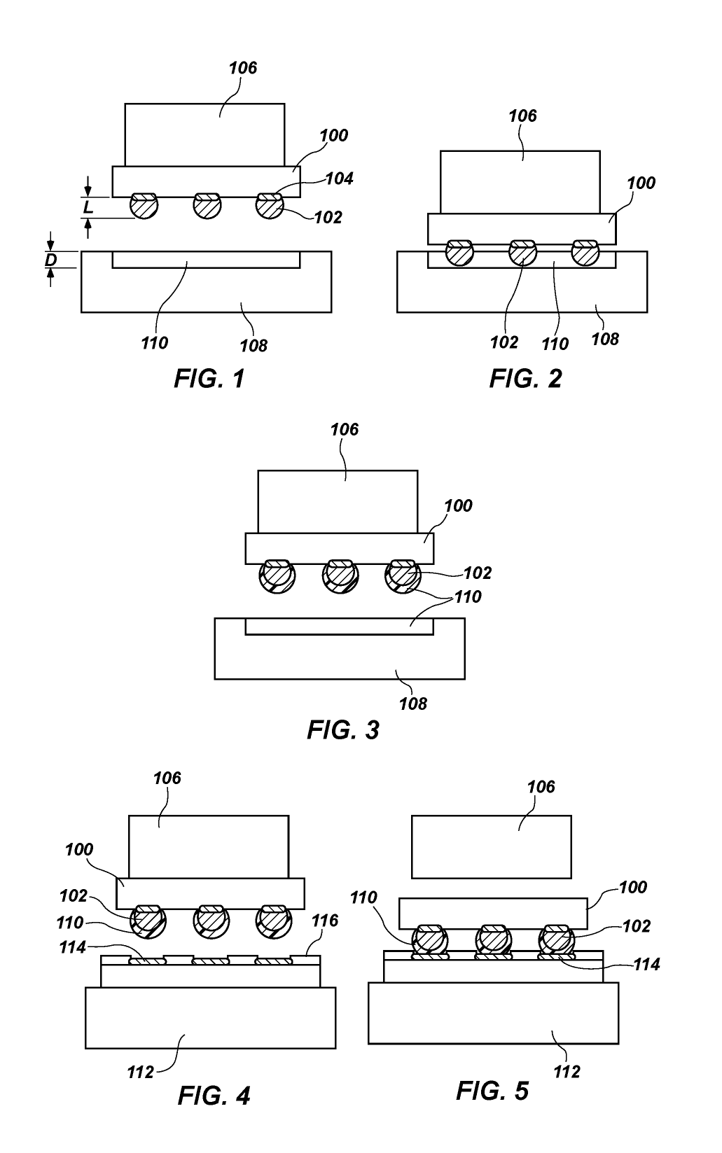

FIGS. 1 through 7 illustrate a method of attaching a semiconductor die 100 to a substrate. Referring to FIG. 1, the semiconductor die 100 may be a conventional semiconductor die including, for example, a dynamic random access memory (DRAM) die, a Flash die, a logic die (e.g., a processor die), a complementary metal oxide semiconductor (CMOS) die, etc. Thus, the methods of the present disclosure are not limited to any particular type of semiconductor die 100. The semiconductor die 100 may include a plurality of conductive structures 102 protruding from a major surface to be used for attaching and electrically coupling the semiconductor die 100 to a substrate. By way of example and not limitation, each of the conductive structures 102 may be a conductive bump or pillar formed on a corresponding conductive pad 104 of the semiconductor die 100, such as a solder bump (e.g., a bump including a silver-tin alloy), a metal pillar, a copper pillar, a solder-tipped metal pillar, etc. The conductive structures 102 may, for example, be arranged in a so-called “ball grid array” (BGA) across a major surface of the semiconductor die 100.

In some embodiments, the plurality of conductive structures 102 may be formed at a fine pitch. Pitch is a concept used to describe a size of adjacent (e.g., repeating) features, and is generally defined as a width of a feature plus a distance between that feature and an immediately adjacent feature. As used herein, the phrase “fine pitch” refers to features having a relatively small pitch. Thus, the conductive structures 102 formed at a fine pitch may be relatively small conductive structures 102 and/or positioned relatively close to one another. By way of example and not limitation, the conductive structures 102 of the present disclosure may have a pitch of about 1000 μm or less, such as between about 40 μm and about 500 μm. In some embodiments, the conductive structures 102 may have a pitch of between about 40 μm and about 100 μm. In other embodiments, the plurality of conductive structures 102 may be formed at an increased pitch (i.e., not at a fine pitch). Of course, the pitch values listed are provided as examples only, and embodiments of the present disclosure may include pitches above or below the listed values.

As shown in FIG. 1, the semiconductor die 100 may be held by a pick head 106 of a so-called “pick and place” device, such as by a vacuum force, on a side of the semiconductor die 100 opposite the conductive structures 102. The pick head 106 may be used to position the semiconductor die 100 over a liquid receptacle 108 (e.g., a so-called “flux tray”) that includes a reservoir of a liquid epoxy flux 110. The liquid epoxy flux 110 may include an epoxy component and a flux component. The epoxy component may include, for example, an epoxy resin and an epoxy curing agent. The epoxy resin may be an electrically insulating material. The flux component may be a chemical component for removing or inhibiting formation of a metal oxide on a surface of the conductive structures 102 during a bonding process, as is known to those of ordinary skill in the art. For example, the flux component may include a carboxylic acid. Other conventional components may be included in the liquid epoxy material 110, such as a tackifier component, a thickening agent, a catalyst material, a flow agent, an adhesion promoter, a dye, etc.

The epoxy flux 110 may be commercially available or may be specifically formulated for a particular application. Examples of commercially available materials that may be used as the epoxy flux 110, in some embodiments, include the following: part number FF6000 available from Henkel Corporation of Düsseldorf, Germany; material of the trade name STAYCHIP™ PRL 50-5D available from Alpha Advanced Materials of Suwanee, Ga.; material of the trade name JPK8 available from Senju Metal Industry Co., Ltd. of Tokyo, Japan; material of the trade name EXP10067 available from LORD Corporation of Cary, N.C.; and materials of the trade names JL-8-22-4 and JL8-106-1, both available from Kester, Inc. of Itasca, Ill..

Referring to FIG. 2, the pick head 106 may be lowered to position the conductive structures 102 at least partially in contact with the liquid epoxy flux 110 in the liquid receptacle 108. A depth D (FIG. 1) of the liquid receptacle 108 may be related to a distance L (FIG. 1) that the conductive structures 102 extend from the major surface of the semiconductor die 100 and to the desired volume of liquid epoxy flux 110 that is to coat the conductive structures 102. The length L that the conductive structures 102 extend from the major surface of the semiconductor die 100 may be selected based on a desired bond line thickness between the semiconductor die 100 and a substrate to which the semiconductor die 100 is to be bonded, as discussed in more detail below. In some embodiments, the depth D may be less than the length L to enable the semiconductor die 100 to be lowered (or the liquid receptacle 108 to be raised) until the conductive structures 102 contact a bottom of the liquid receptacle 108. In other embodiments, the depth D may be greater than the length L, and the semiconductor die 100 may be lowered (or the liquid receptacle 108 may be raised) until a desired amount of the conductive structures 102 and/or of the major surface of the semiconductor die 100 is contacted by the liquid epoxy flux 110. If the depth D is greater than the length L, the semiconductor die 100 may be lowered (or the liquid receptacle 108 may be raised) until the major surface of the semiconductor die 100 laterally outside of the conductive structures 102 contacts a top surface of the liquid receptacle 108.

The viscosity and tackiness of the liquid epoxy flux 110 in the liquid receptacle 108 may be tailored to enable a desired volume of the liquid epoxy flux 110 to be formed on the conductive structures 102 and to enable the conductive structures 102 to be dipped into the liquid epoxy flux 110 and removed without becoming stuck in the liquid epoxy flux 110. For example, the liquid epoxy flux 110 may be heated to reduce the viscosity thereof or cooled to increase the viscosity thereof. Alternatively or additionally, the chemical components of the liquid epoxy flux 110 may be selected such that the liquid epoxy flux 110 exhibits a desired viscosity and tackiness. In addition, an amount of time that the conductive structures 102 are positioned in the liquid receptacle 108 may be altered to alter a volume of liquid epoxy flux 110 formed on the conductive structures 102.

Referring to FIG. 3, the pick head 106 may be lifted to remove the conductive structures 102 from the liquid receptacle 108. At least a portion of outer surfaces of the conductive structures 102 may be covered by a volume of the liquid epoxy flux 110. As shown in FIG. 3, each conductive structure 102 may be at least partially covered by a separate volume of the liquid epoxy flux 110. In other embodiments, the liquid epoxy flux 110 may also be formed between the conductive structures 102, such as on the major surface of the semiconductor die 100 between the conductive structures 102, such that a single, continuous volume of the liquid epoxy flux 110 may cover more than one, or even all, of the conductive structures 102.

Although FIGS. 1 through 3 have been described with reference to covering the conductive structures 102 with liquid epoxy flux 110 by dipping the conductive structures 102 into the liquid epoxy flux 110 in the liquid receptacle 108, the present disclosure is not so limited. For example, in other embodiments, the liquid epoxy flux 110 may be formed over the conductive structures 102 by, for example, spraying the liquid epoxy flux 110 over the conductive structures 102, printing the liquid epoxy flux 110 over the conductive structures, or any other method of forming a liquid epoxy material onto the conductive structures 102.

Referring to FIG. 4, after a volume of the liquid epoxy flux 110 is formed on at least a portion of the conductive structures 102, the semiconductor die 100 may be positioned over a substrate 112 and the conductive structures 102 may be aligned with respective bond pads 114 of the substrate 112. The substrate 112 may be any substrate with which the semiconductor die 100 is to be physically and electrically coupled. By way of example and not limitation, the substrate 112 may be a printed circuit board (PCB), an interposer, a logic die, a processor die, a lead frame, or another semiconductor die substantially similar to the semiconductor die 100. The substrate 112 may include the bond pads 114, which in the case of the substrate being a PCB or any interposer may alternatively be characterized as terminal pads 114, arranged in a pattern corresponding to a pattern of the plurality of conductive structures 102. In addition, the substrate may include a solder mask 116 (e.g., a dielectric material configured to inhibit solder material from flowing laterally around the bond pads 114). The substrate 112 may also include other components, structures and materials, such as (depending on the structure and function of the substrate 112 and without limitation), transistors, capacitors, dielectric materials, conductive traces, conductive vias, a redistribution layer, a build-up layer, a passivation layer, etc., as is known in the art.

Referring to FIG. 5, the semiconductor die 100 may be placed on the substrate 112. The conductive structures 102 may be placed on and contact the bond pads 114 through the liquid epoxy flux 110. If the liquid epoxy flux 110 is sufficiently flowable, the weight of the semiconductor die 100, the force of the pick head 106, or a combination thereof may cause the liquid epoxy flux 110 to flow and one or more of the conductive structures 102 may directly contact a respective one or more bond pads 114. As shown in FIG. 5, after placing the semiconductor die 100 on the substrate 112, the pick head 106 may release the semiconductor die 100 and be withdrawn.

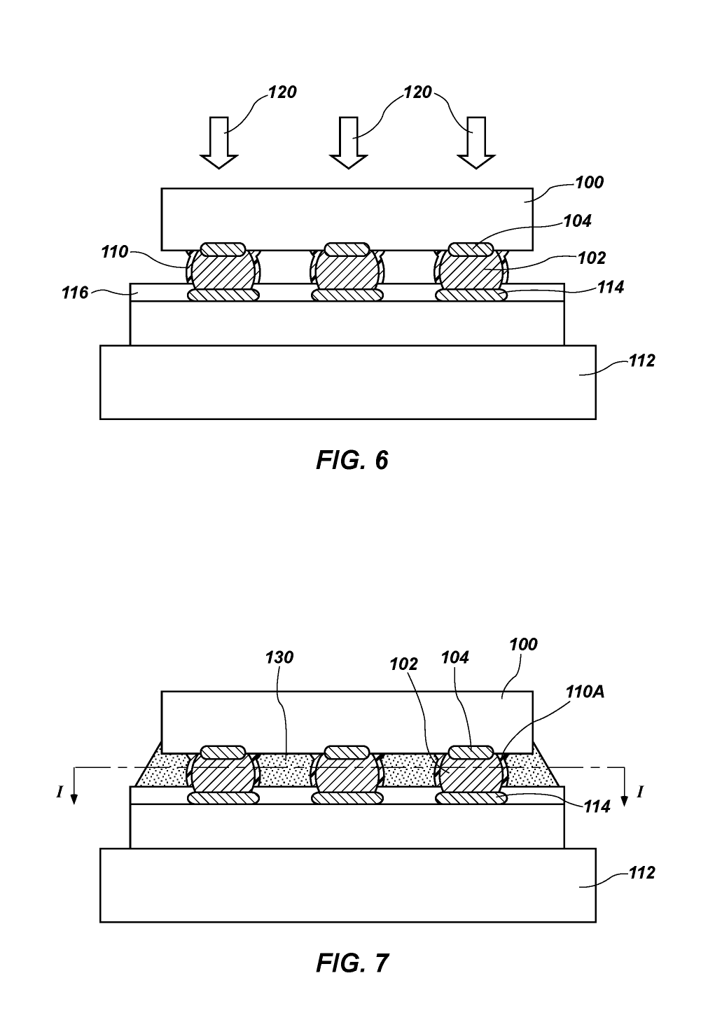

Referring to FIG. 6, the semiconductor die 100 may be electrically coupled to the substrate 112 through the plurality of conductive structures 102, which may be positioned in a volume between the semiconductor die 100 and the substrate 112. By way of non-limiting example, the semiconductor die 100 may be pressed toward the substrate 112, as shown with arrows 120 representing the application of force, to cause the conductive structures 102 to physically and electrically contact the bond pads 114. In some embodiments, heat may also be applied to the structure to at least partially soften or melt the conductive structures 102 or portions thereof to form a bond between the conductive structures 102 and the bond pads 114. As the conductive structures 102 are pressed against the bond pads 114 and/or melted, the liquid epoxy flux 110 may flow away from the bonding interface and toward outer side surfaces of the conductive structures 102. Thus, a bonding interface between the conductive structures 102 and the bond pads 114 may be substantially free of the epoxy flux 110, such that a direct physical and electrical bond may be formed between the conductive structures 102 and the respective bond pads 114. In addition, the liquid epoxy flux 110 may extend substantially continuously from the solder mask 116, along the outer side surfaces of the conductive structures 102, to a major surface of the semiconductor die 100 facing the volume, to form a barrier around each of the conductive structures 102.

The formation of the physical bond between the conductive structures 102 and the bond pads 114 may form a plurality of mechanical and electrical connections that extend from the conductive pads 104, through the conductive structures 102, and to the bond pads 114. Thus, electrical communication pathways, which also provide mechanical attachment points, may be established between the semiconductor die 100 and the substrate 112 through the conductive structures 102.

Heat may be applied to the structure illustrated in FIG. 6 to at least partially cure the liquid epoxy flux 110. The heat may induce a chemical reaction to cross-link the epoxy resin component. Such cross-linking may harden and mechanically strengthen the epoxy component of the epoxy flux 110. In addition, any volatile components of the epoxy flux 110, such as the flux component, may at least partially evaporate when exposed to the heat of the cure process. Due to the loss of the flux component and, possibly, other components, the epoxy flux 110 may shrink in volume, thickness, and mass. For example, the epoxy component of the epoxy flux 110 that remains after the heat is applied and the epoxy flux 110 is cured may be between about 10% and about 25% by weight of the epoxy flux 110 as initially applied to the conductive structures 102. Thus, the epoxy flux 110 may be converted from the liquid epoxy flux 110 into a hardened epoxy 110A (see FIGS. 7 through 9) by the application of heat.

In some embodiments, at least a portion of the heat may be applied to the structure while the semiconductor die 100 is pressed toward the substrate 112, such as in a so-called “thermal compression” process. In other embodiments, sufficient heat may be applied to the structure to melt or soften the conductive structures 102 or portions thereof in a so-called “reflow” process, which may involve application of heat over a longer amount of time compared to the thermal compression process. The reflow process may be performed in conjunction with or without the application of force (indicated by arrows 120) of the semiconductor die 100 toward the substrate 112. In some embodiments, additional heat may be applied after the semiconductor die 100 is pressed toward the substrate 112, the thermal compression process, and/or the reflow process, to more fully cure the epoxy flux 110 and to evaporate at least a portion of the flux component thereof. One of ordinary skill in the art will be capable of selecting the specific temperatures and amounts of time sufficient to cure the epoxy flux 110, depending on, for example, the specific chemical components of the selected epoxy flux 110.

Referring to FIG. 7, after the conductive structures 102 are bonded to the bond pads 114 and the epoxy flux 110 is cured to become the epoxy 110A, an underfill material 130 may be disposed in a volume between the semiconductor die 100 and the substrate 112 and adjacent to the conductive structures 102. The underfill material 130 may be introduced into the volume using a conventional technique, such as by dispensing liquid underfill material 130 proximate one or more edges of the semiconductor die 100 and allowing capillary forces to draw the underfill material 130 into the volume. In some embodiments, such capillary action may be supplemented, and formation of voids reduced, either by applying a pressure above atmospheric pressure to force the underfill material 130 into the volume or by applying a reduced pressure (e.g., vacuum) to draw any gases (e.g., air) out of the volume and draw the underfill material 130 into the volume. The underfill material 130 may at least substantially fill the volume between the semiconductor die 100 and the substrate 112 and adjacent to and laterally surrounding the conductive structures 102. The epoxy 110A along the outer side surfaces of the conductive structures 102 may form a physical and insulating (e.g., dielectric) barrier between the conductive structures 102 and the underfill material 130. The epoxy 110A may laterally encapsulate the conductive structures 102, substantially reducing or even preventing the potential for shorting between conductive structures 102 through the intervening underfill material 130. The epoxy 110A may also provide mechanical support to the conductive structures 102 and mechanical strength to the connection between semiconductor die 100 and substrate 112.

The underfill material 130 may include a polymer matrix and a thermally conductive material (i.e., a filler material), which may be in the form of particles. As used herein, the term “thermally conductive material” means and includes a material exhibiting at least greater thermal conductivity than a thermal conductivity of a matrix material in which the thermally conductive material is dispersed. The thermally conductive material may be used to improve heat transfer through the underfill material 130 compared to underfill materials without such a thermally conductive material. Many materials that exhibit relatively high thermal conductivity, such as metals, are also electrically conductive. Thus, in some embodiments, the thermally conductive material of the underfill material 130 may be or include electrically conductive particles of metal or another material.

The polymer matrix of the underfill material 130 may be or include, for example, an epoxy material, a silicone material, a modified silicone material, or an acrylate material. By way of example and not limitation, the thermally conductive material may be a metal or metal alloy material. By way of another example, the thermally conductive material may include at least one of silver, gold, copper, tin, indium, lead, aluminum, alloys thereof, solder alloys, and combinations thereof. The thermally conductive material of the underfill material 130 may be in the form of particles of any shape. For example, the particles of the thermally conductive material may be in the form of spheres, flakes, fibers, or irregular shapes. The surface of each of the particles may be smooth or rough. The amount of thermally conductive material may be at least about 50% by weight of the underfill material 130 before curing. In some embodiments, the amount of thermally conductive material may be between about 60% and about 95% by weight of the underfill material 130. In some embodiments, the amount of thermally conductive material may be between about 75% and about 90% by weight of the underfill material 130. In a particular embodiment, the amount of thermally conductive material may be about 86% by weight of the underfill material 130. Such high loading amounts of thermally conductive material may generally cause the underfill material 130, as a whole, to be electrically conductive as well as thermally conductive. However, the electrically insulating barrier between the conductive structures 102 and the underfill material 130 formed by the epoxy 110A may enable the use of such an electrically conductive underfill material 130 for semiconductor device packages including the fine pitch conductive structures 102. Thus, the epoxy 110A may enable highly thermally conductive underfill materials 130 to be used, without restrictions as to the electrical conductivity thereof.

To facilitate flow of the underfill material 130, including the thermally conductive material, into the volume between the semiconductor die 100 and the substrate 112, the average diameter of the particles of thermally conductive material may be about one third of a bond line thickness or less. The bond line thickness may be defined by a shortest vertical distance across the volume between the semiconductor die 100 and the substrate, not including the conductive structures 102. In other words, the bond line thickness is equivalent to a film thickness of the underfill material 130 between the semiconductor die 100 and the substrate 112. By way of example and not limitation, the bond line thickness between the semiconductor die 100 and the substrate may be between about 10 μm and about 100 μm, for example between about 20 μm and about 30 μm. The size of the particles of thermally conductive material may be substantially smaller than the bond line thickness, to prevent bridging and compromise of the bond line and to prevent mechanical stress-induced perforation of epoxy 110A that laterally encapsulates conductive structures 102. Thus, in some embodiments, the maximum particle size (e.g., diameter) of the thermally conductive material may about 30 μm or less, such as less than about 20 μm, less than about 3 μm, or even less than about 1 μm. Where a bond line is between about 20 μm and about 30 μm in depth, a maximum particle size may be less than about 3 μm. In some embodiments, the maximum particle size of the thermally conductive material may be between about 500 nm and about 25 μm.

The underfill material 130 including the thermally conductive material may be commercially available or may be specifically formulated for a particular application. Examples of commercially available materials that may be used as the underfill material 130 in some embodiments include the following: materials of the trade names EN-4920T_U-5677-011 (having an acrylate matrix and silver powder filler, the silver powder filler constituting about 86% by weight of the material) and EN-4620K (having an epoxy matrix and silver powder filler, the silver powder filler constituting between about 75% and 95% by weight of the material), both available from Hitachi Chemical Co., Ltd. of Tokyo, Japan; materials of the trade names MT-315 and MT-141 (each having an epoxy matrix and a silver filler, the silver filler constituting between about 75% and about 80% by weight of the material), both available from LORD Corporation of Cary, N.C.; materials of the trade names EPO-TEK® H20S (having an epoxy matrix and a silver flake filler) and EPO-TEK® H20S-D (having an epoxy matrix and a silver flake filler, the silver flake filler constituting between about 60% and 75% by weight of the material), both available from Epoxy Technology, Inc. of Billerica, Mass.; material of the trade name 84-1LMISR4 (having an epoxy matrix and a silver filler), available through the ABLESTIK® brand of Henkel Corporation of Dusseldorf, Germany; material of the trade name 260C (having an epoxy matrix and a copper and tin alloy filler, the copper and tin alloy filler constituting about 86% by weight of the material) available from Ormet Circuits, Inc. of San Diego, Calif.; material of the trade name DA-6534 (having a modified silicone matrix and a silver flake filler, the silver flake filler constituting about 60% by weight of the material) available from Dow Corning Corporation of Midland, Mich.; material of the trade name X-23-7835-5 (having a silicone matrix and an indium filler) available from Shin-Etsu Chemical Co., Ltd. of Tokyo, Japan; and material of the trade name APS1E (having an epoxy matrix and a copper and solder filler, the copper and solder filler constituting between about 80% and about 90% by weight of the material) available from Honeywell International Inc. of Morris Township, N.J.

By way of example and not limitation, while the polymer matrix of the underfill material may exhibit a relatively low thermal conductivity, for example on the order of about 1.3 W/mK, the selected underfill material 130, as a whole, may exhibit a thermal conductivity up to, for example, about 300.0 W/mK. In some embodiments, the underfill material 130 may exhibit a thermal conductivity of at least about 1.0 W/mK, such as between about 10.0 W/mK and about 30.0 W/mK. In some embodiments, the underfill material 130 may exhibit a thermal conductivity of between about 10 W/mK and about 200.0 W/mK. The underfill material 130 may, in some embodiments, be a thermal interface material (“TIM”) conventionally used for filling gaps in an interface between a component (e.g., a semiconductor device) and a heat sink.

Electrically conductive materials (e.g., TIMs) are not conventionally used as underfill materials, particularly in semiconductor device packages with fine pitch conductive structures 102 like those described herein, because the electrical conductivity thereof would have a high likelihood of causing the conductive structures 102 to undesirably electrically communicate (i.e., form electrical connections) with each other through the underfill materials, as described above. However, as noted above, the electrically insulating barrier formed by the epoxy 110A along outer side surfaces of the conductive structures 102 of the present disclosure enables the use of the electrically conductive underfill materials 130, which are also highly thermally conductive, compared to underfill materials that are not electrically conductive and/or that do not include electrically conductive filler materials.

After the underfill material 130 is disposed in the volume between the semiconductor die 100 and the substrate 112, the underfill material 130 may be cured (e.g., solidified). Depending on the type of underfill material 130 used, the underfill material 130 may be cured by, for example, application of heat or exposure to radiation, such as ultraviolet radiation. The curing of the underfill material 130 may, in some embodiments, cause the polymer matrix of the underfill material 130 to chemically bond to the epoxy 110A. Such chemical bonds, if present, may inhibit formation of voids and/or stress concentrations at an interface between the underfill material 130 and the epoxy 110A.

Accordingly, the present disclosure includes methods of attaching a semiconductor die to a substrate. In accordance with such methods, the semiconductor die may be electrically coupled to a substrate using a plurality of fine pitch conductive structures. At least an outer side surface of each fine pitch conductive structure of the plurality of fine pitch conductive structures may be covered with an electrically insulating material. A thermally conductive material may be disposed between the semiconductor die and the substrate. The thermally conductive material may include a plurality of thermally conductive particles and a polymer matrix.

In addition, the present disclosure includes methods of forming a semiconductor device package. In accordance with such methods, a plurality of fine pitch conductive structures of a semiconductor device may be at least partially coated with an electrically insulating material. The plurality of fine pitch conductive structures may be electrically coupled to a corresponding plurality of bond pads of a substrate. An underfill material may be disposed in a volume between the semiconductor device and the substrate. The underfill material may have a plurality of thermally conductive particles dispersed therein.

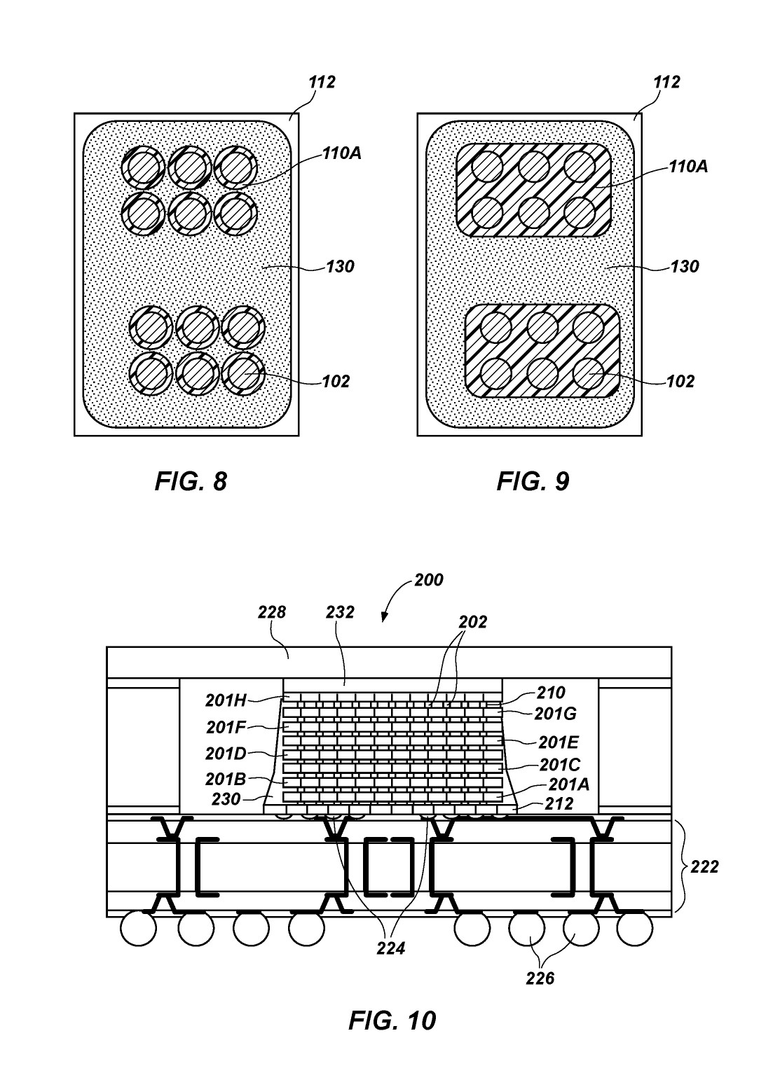

Referring to FIG. 8, a cross-sectional top-down view of the structure of FIG. 7 is shown, taken through the volume between the semiconductor die 100 and the substrate 112, along line I-I of FIG. 7. As shown in FIG. 8, in some embodiments, each conductive structure 102 of the plurality of conductive structures 102 may have a distinct volume of epoxy 110A along an outer side surface thereof. The underfill material 130 may be disposed over the substrate 112, including between immediately adjacent conductive structures 102 of the plurality of conductive structures 102.

Referring to FIG. 9, a cross-sectional top-down view similar to the view of FIG. 8 is shown, except more than one conductive structure 102 of the plurality of conductive structures 102 may have a common volume of epoxy 110A surrounding outer side surfaces thereof. Thus, the underfill material 130 may not be disposed between at least some immediately adjacent conductive structures 102 of the plurality of conductive structures 102.

In additional embodiments, a single, continuous volume of the epoxy 110A may cover more than one of the conductive structures 102, but may not fully fill the volume between the semiconductor die 100 (FIG. 7) and the substrate 112 and between immediately adjacent conductive structures 102. In such a case, more than one of the conductive structures 102 may be covered by a single, continuous volume of the epoxy 110A, but some underfill material 130 may still be disposed in the unfilled volume between immediately adjacent conductive structures 102.

Referring to FIG. 10, a semiconductor device package 200 is illustrated that includes a plurality of semiconductor memory (e.g., DRAM) dice 201A through 201H stacked and electrically coupled through a first plurality of conductive structures 202, which may have a fine pitch. The plurality of semiconductor memory dice 201A through 201H may be stacked over a semiconductor logic die 212. The semiconductor logic die 212 may be a processor, such as an application specific integrated circuit (ASIC) processor or a central processing unit (CPU) processor. The semiconductor memory dice 201A through 201H may be electrically coupled to the semiconductor logic die 212 through a second plurality of conductive structures 202, which may have a fine pitch. The semiconductor logic die 212 may be electrically coupled to a printed circuit board (PCB) 222 through, for example, a third plurality of conductive structures 224, which may have a fine pitch, although the pitch of the third plurality of conductive structures 224 may be larger than a pitch of the first and second pluralities of conductive structures 202. The PCB 222 may include fourth plurality of conductive structures 226 for electrically coupling the PCB 222 to a higher level substrate, such as a mother board, for example. The fourth plurality of conductive structures 226 may also have a fine pitch, although the pitch of the fourth plurality of conductive structures 226 may be larger than the respective pitches of the first and second pluralities of conductive structures 202 and/or the third plurality of conductive structures 224. In some embodiments, the fourth plurality of conductive structures 226 may not have a fine pitch.

A heat sink 228 (e.g., a copper plate) may be positioned over the stack of semiconductor memory dice 201A through 201H to draw heat away from the semiconductor memory dice 201A through 201H and the semiconductor logic die 212. A thermal interface material (TIM) 232 may be disposed between the top semiconductor memory die 201H and the heat sink 228 for improved heat transfer therebetween.

An underfill material 230, formulated as one of the underfill materials 130 described above or of other electrically conductive formulation to provide a desired thermal conductivity, may be disposed in any or all of the volumes between semiconductor dice (e.g., between any of the semiconductor memory dice 201A through 201H and the semiconductor logic die 212), between a semiconductor die and a substrate (e.g., between the semiconductor logic die 212 and the PCB 222), and between a substrate and a higher level substrate (e.g., between the PCB 222 and a mother board). As explained above, the underfill material 230 may include a thermally conductive material that may also be an electrically conductive material, such that the underfill material 230 as a whole may be electrically conductive. In any volume in which the underfill material 230 is disposed, at least an outer side surface of the corresponding conductive structures 202, 224, and/or 226 may be covered by an electrically insulating material 210 (e.g., an epoxy), as described above with reference to the epoxy flux 110 and the epoxy 110A. The electrically insulating material 210 is shown in FIG. 10 as covering only the first plurality of conductive structures 202 for simplicity, although outer side surfaces of the second, third, and/or fourth pluralities of conductive structures 202, 224, and/or 226 may alternatively or additionally be covered by the electrically insulating material 210.

In some embodiments, the volume between each of the semiconductor memory dice 201A through 201H may be filled with the underfill material 230 including the electrically and thermally conductive material. In addition, the volume between the lower semiconductor memory die 201A and the semiconductor logic die 212 may be filled with the underfill material 230. Outer side surfaces of each of the conductive structures 202 electrically coupling the semiconductor memory dice 201A through 201H to each other and to the semiconductor logic die 212 may be covered by the electrically insulating material 210. Thus, an overall thermal resistance of the stack of semiconductor dice (including the semiconductor logic die 212 and the semiconductor memory dice 201A through 201H) may be reduced, and an operating temperature of the components (e.g., the semiconductor memory dice 201A through 201H and the semiconductor logic die 212) of the semiconductor device package 200 may be lower, compared to semiconductor device packages that do not include the underfill material 230 including an electrically and thermally conductive material. Accordingly, the underfill material 230 may improve performance, refresh rates, and reliability of the semiconductor device package 200 compared to conventional semiconductor device packages by enabling the semiconductor device package 200 to be operated at a lower die temperature.

Accordingly, the present disclosure includes semiconductor devices that include a substrate and at least one semiconductor die electrically coupled to the substrate through a plurality of fine pitch conductive structures. An underfill material may be disposed in a volume between the substrate and the at least one semiconductor die and adjacent the plurality of fine pitch conductive structures. The underfill material may comprise a thermally conductive material. The semiconductor device may also include an electrically insulating material disposed between the plurality of fine pitch conductive structures and the underfill material.

In addition, the present disclosure includes semiconductor device packages including a semiconductor logic die and a plurality of semiconductor memory dice stacked over the semiconductor logic die. A plurality of conductive structures may electrically couple adjacent dice of the plurality of semiconductor memory dice and the semiconductor logic die to each other. An electrically insulating material may cover outer side surfaces of each conductive structure of the plurality of conductive structures. A thermally and electrically conductive material may be disposed in a polymer matrix between the adjacent dice of the semiconductor logic die and the plurality of semiconductor memory dice.

The embodiments of the disclosure described above and illustrated in the accompanying drawing figures do not limit the scope of the invention, since these embodiments are merely examples of embodiments of the disclosure. The invention is defined by the appended claims and their legal equivalents. Any equivalent embodiments lie within the scope of this disclosure. Indeed, various modifications of the present disclosure, in addition to those shown and described herein, such as alternative useful combinations of the elements described, will become apparent to those of ordinary skill in the art from the description. Such modifications and embodiments also fall within the scope of the appended claims and their legal equivalents.

What is claimed is:

1. A method of stacking a semiconductor chip having at least one conductive structure onto a substrate having at least one bond pad, the method comprising:
covering a surface of the at least one conductive structure with an adhesive epoxy material comprising an insulating material;
aligning the at least one conductive structure with the at least one bond pad of the substrate and stacking the semiconductor chip onto the substrate; and
removing a portion of the adhesive epoxy material from the at least one conductive structure to connect the at least one conductive structure and the at least one bond pad.

2. The method of claim 1, further comprising selecting the adhesive epoxy material to comprise an epoxy component and a flux component, the flux component comprising a material formulated to remove metal oxides from surfaces of the conductive structure.

3. The method of claim 1, further comprising selecting the adhesive epoxy material further to comprise at least one of a tackifier component, a thickening agent, a catalyst material, a flow agent, or an adhesion promoter.

4. The method of claim 1, wherein covering a surface of the at least one conductive structure with an adhesive epoxy material comprises dipping the at least one conductive structure into a liquid receptacle that includes a reservoir of the adhesive epoxy material.

5. The method of claim 1, further comprising heating the semiconductor chip to cure the adhesive epoxy material covering a side surface of the at least one conductive structure.

6. The method of claim 1, wherein connecting the at least one conductive structure and the at least one bond pad comprises heating the semiconductor chip to melt at least some of the at least one conductive structure.

7. The method of claim 11, wherein connecting the at least one conductive structure and at least one the bond pad comprises pressing the semiconductor chip toward the substrate.

8. The method of claim 11, further comprising filling a volume between the semiconductor chip and the substrate with an underfill material comprising conductive particles.

9. A method of stacking a semiconductor chip having a plurality of conductive structures onto a substrate having a plurality of bond pads, the method comprising:
covering surfaces of the plurality of conductive structures with an adhesive epoxy material comprising an insulating material to form a plurality of covered conductive structures;
disposing the plurality of covered conductive structures over the plurality of bond pads to stack the semiconductor chip on the substrate;
removing portions of the adhesive epoxy material from surfaces of the plurality of covered conductive structures between the plurality of covered conductive structures and the bond pads and electrically connecting the plurality of covered conductive structures to the respective plurality of bond pads.

10. The method of claim 9, further comprising selecting the adhesive epoxy material to comprise an epoxy component and a flux component, the flux component comprising a material formulated to remove metal oxides from surfaces of the conductive structure.

11. The method of claim 9, further comprising selecting the adhesive epoxy material further to comprise at least one of a tackifier component, a thickening agent, a catalyst material, a flow agent, or an adhesion promoter.

12. The method of claim 9, wherein covering surfaces of the plurality of conductive structures with an adhesive epoxy material comprises positioning the semiconductor chip over a liquid receptacle comprising a reservoir of the adhesive epoxy material, dipping the plurality of conductive structures into the adhesive epoxy material to form the plurality of covered conductive structures, and removing the plurality of conductive structures from the liquid receptacle.

13. The method of claim 9, further comprising disposing a volume of the adhesive epoxy material around a plurality of the conductive structures and disposing a volume of a thermally and electrically conductive underfill material around the volume of the adhesive epoxy material.

14. The method of claim 9, further comprising heating the semiconductor chip to cure the adhesive epoxy material covering side surfaces of the plurality of covered conductive structures.

15. The method of claim 9, wherein electrically connecting the plurality of covered conductive structures to the respective plurality of the bond pads comprises heating the semiconductor chip to a temperature to melt at least a portion of each covered conductive structure of the plurality of covered conductive structures.

16. The method of claim 9, wherein electrically connecting the plurality of covered conductive structures to the respective plurality of bond pads comprises pressing the semiconductor chip toward the substrate.

17. The method of claim 9, further comprising filling a volume between the semiconductor chip and the substrate with an underfill material comprising electrically and thermally conductive particles.

18. A method of stacking a semiconductor chip having a plurality of conductive structures on a substrate having a plurality of bond pads, the method comprising:
dipping the plurality of conductive structures in an adhesive epoxy material comprising an insulative material to cover outer surfaces of the plurality of conductive structures with the adhesive epoxy material;
stacking the semiconductor chip onto the substrate and coupling the plurality of conductive structures to respective bond pads of the plurality of bond pads; and
electrically coupling the plurality of conductive structures to the respective bond pads of the plurality of bond pads.

19. The method of claim 18, wherein electrically coupling the plurality of conductive structures to the respective bond pads of the plurality of bond pads comprises removing a portion of the adhesive epoxy material from each of the plurality of the conductive structures.

20. The method of claim 18, further comprising filling a volume between the semiconductor chip and the substrate with an underfill material comprising electrically and thermally conductive particles.
